(19) United States
(12) Patent Application Publication
(10) Pub. No.: US 2026/0177192 A1
(43) Pub. Date: Jun. 25, 2026

(54) Display Apparatus

(71) Applicant: Exquisite Gaming Limited, Essex (GB)

(72) Inventors: Alan FENWICK, Essex (GB); Christopher JOBSON, Essex (GB)

(21) Appl. No.: 19/429,028

(22) Filed: Dec. 22, 2025

(30) Foreign Application Priority Data
Dec. 23, 2024 (GB) 2418998.7

(51) Int. Cl. F16M 11/10; H04R 1/02; H05K 5/02

(52) U.S. Cl. CPC F16M 11/10; H04R 1/028; H05K 5/0247; F16M 2200/065; F16M 2200/066

(57) ABSTRACT

Display apparatus 100,400, which comprises a body section, the body section comprising an upstanding wall 120,410 and a shelf 200,500. The shelf 200,500 is pivotally mounted to the body section, and moveable between a stowed position and a deployed position. When the shelf 200,500 is in the deployed position, the shelf 200,500 is pivoted away from the upstanding wall 120,410 so as to provide a surface for retaining an object, and wherein the upstanding wall 120,410 of the body section is disposed in a position where it is tilted from the vertical by the shelf 200,500. The shelf may further comprise a pivotally attached foot 230,530, and the apparatus 100,400 may further comprise a stand 310,620.

This invention is display apparatus, and in particular display apparatus for displaying objects for viewing by a user, such as cellular or smart telephones, books, tablets and the like.

Users may wish to view various objects, for example to watch and listen to videos on an electronic device, or to read a book or electronic book (also known as an “E-Book”, which can be read on a device such as a so-called “E-Reader”), without having to hold their device or book. For this purpose, a user might also have headphones such as wireless headphones including in-ear headphones, which may include headphones commonly referred to as earbuds. Situations where a user may wish to view their device and either listen to the soundtrack of a video or separately listen to music or white noise may include travelling on public transport or working from a desk or table in a public area. The user then has the difficulty of having to rest their device at an appropriate angle to view whilst also having to manage items such as the case of their headphones.

The present invention provides display apparatus which provides a user with a suitable resting surface for their object such as an electronic device and optionally provides storage for their earbuds or similar electronic devices.

Therefore, according to this invention there is provided display apparatus comprising: a body section, the body section comprising an upstanding wall; and a shelf, the shelf being pivotally mounted to the body section, and moveable between a stowed position and a deployed position, wherein, when the shelf is in the deployed position, the shelf is pivoted away from the upstanding wall so as to provide a surface for retaining an object, and wherein the upstanding wall of the body section is disposed in a position where it is tilted from the vertical by the shelf.

The display apparatus may comprise a box or case for containing or storing devices such as earbuds or the like, or may alternatively comprise a device such as a power pack, and in which case the walls of the body section may define an interior which may further comprise one or more recess for storage of objects. Alternatively, the display apparatus may comprise an open sleeve into which an object such as a storage box for earbuds or a power pack can be inserted and wherein the upstanding wall defines an enclosure for storage of such an object.

The display apparatus may further comprise a base, from which the upstanding wall extends. The base or the upstanding wall may further comprise a charging socket, such as a USB socket.

Advantageously, the display apparatus makes it simple to retain, and then view, an object such as a cellular/smart telephone, tablet, E-Reader, books or the like. Furthermore, the shelf permits the display apparatus to be tilted away from the vertical to make it easier to view the object from above such as in a normal reading position, and also to prevent the object from falling over. As described herein, the term “tilted from the vertical” refers to the display apparatus resting on a horizontal surface, with the upstanding wall extending substantially vertically, or perpendicularly to the plane of the surface, when the shelf is in the stowed position. Therefore, when the shelf is in the deployed position, the upstanding wall is titled from that vertical position by the shelf.

The shelf may be pivotally mounted adjacent a lower edge of the upstanding wall. In the stowed position, the shelf may be pivotally mounted up against the upstanding wall of the body section. The upstanding wall may optionally comprise a recess to retain the shelf in the stowed position, so that the walls and shelf are flush when the shelf is in the stowed position.

The shelf may be substantially planar. The shelf may be substantially rectangular.

The shelf may comprise an upper surface for retaining the object when in the deployed position, and a lower surface. The upper surface may comprise an anti-slip coating, or may comprise a profiled or dimpled surface to prevent the object from slipping. The shelf may be pivotally mounted at one end to the upstanding wall with a hinge. The other end of the shelf may comprise a projection or lip to provide an abutment surface for the object.

The lower surface of the shelf may further comprise a pivotally mounted foot, said foot being moveable between a stowed position adjacent the shelf, and a deployed position pivoted away from a lower surface of the shelf, the foot, when the foot and shelf are both in the deployed position, contacting a surface so as to tilt the upstanding wall away from the vertical. The foot, when in the deployed position, may therefore provide a contact point with the surface, permitting the display apparatus to be tilted from the vertical and retained in that position, with a lower edge of the upstanding wall forming a further contact point with the surface. In such embodiments, the shelf could be hingedly deployable to a position perpendicular to the upstanding wall to provide a support to retain the object, with the wall of the apparatus forming a backboard to also support the object.

The body section may further comprise a stand, the stand being pivotally mounted to the upstanding wall on an opposite side of the body section to the shelf, the stand being moveable between a stowed position and a deployed position, wherein when the stand is in the deployed position, the stand contacts a surface so as to tilt the upstanding wall away from the vertical. The stand, if provided, will provide further stability to the display apparatus when it is tilted from the vertical.

The body section further comprises a lid, and the lid may be hingedly mounted to an upper edge of the upstanding wall of the body section. The hinge may be disposed on an opposed side of the body section to the shelf.

Alternatively, the shelf may comprise a clasp for clasping the lid into a closed position or the shelf may extend beyond the upstanding wall, and the lid may comprise an aperture to retain the shelf and prevent its deployment when the lid is shut.

So that it may be better understood, embodiments of the present invention will now be described, by way of example only, with reference to the following Figures wherein:

FIG. 1 shows a front view of a first embodiment of display apparatus according to the present invention;

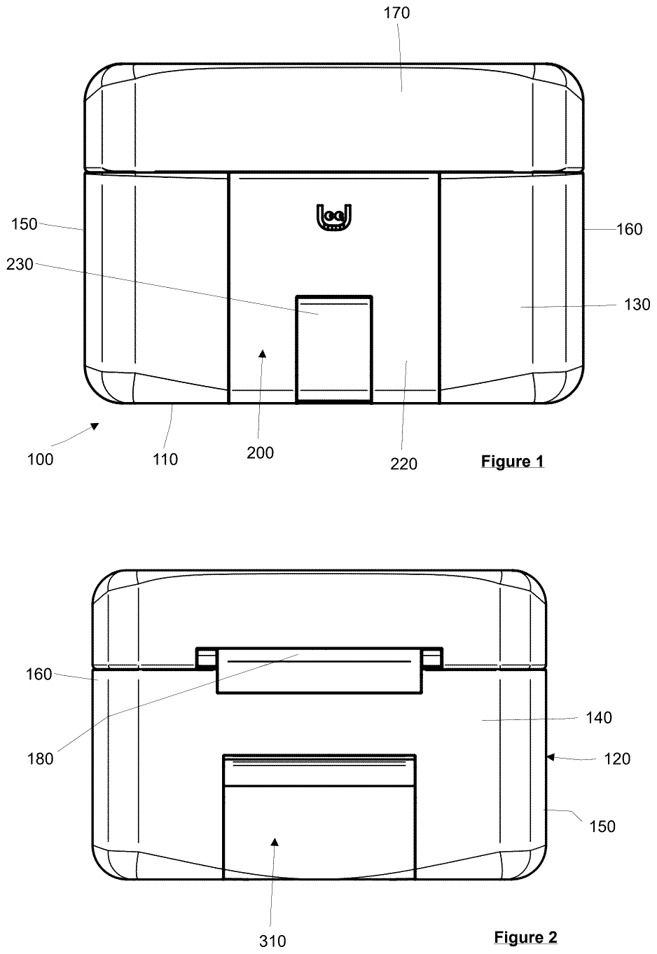

FIG. 2 shows a rear view of the embodiment shown in FIG. 1;

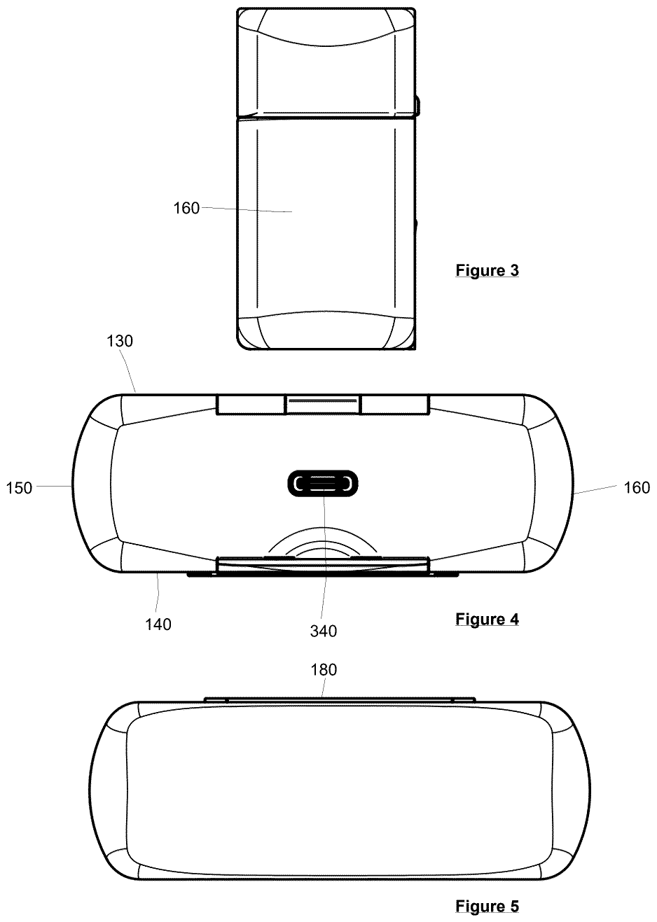

FIG. 3 shows a side view of the embodiment shown in FIGS. 1 and 2;

FIG. 4 shows an underside view of the embodiment shown in FIGS. 1 to 3;

FIG. 5 shows a top view of the embodiment shown in FIGS. 1 to 4;

FIG. 6 shows a side view of the embodiment shown in FIGS. 1 to 5 with a shelf, foot and stand in a deployed position;

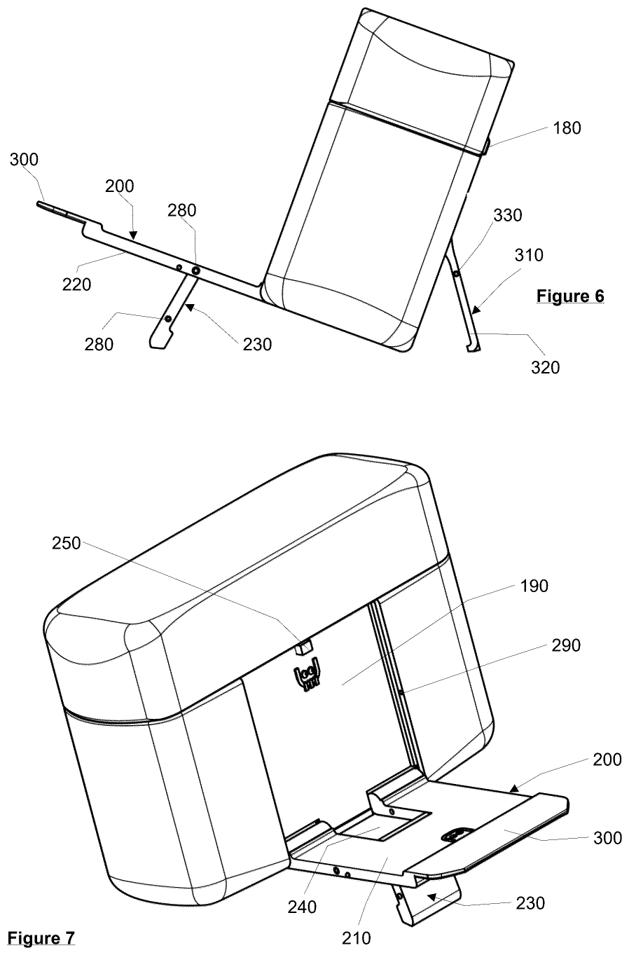

FIG. 7 shows a perspective view of the embodiment of FIG. 6;

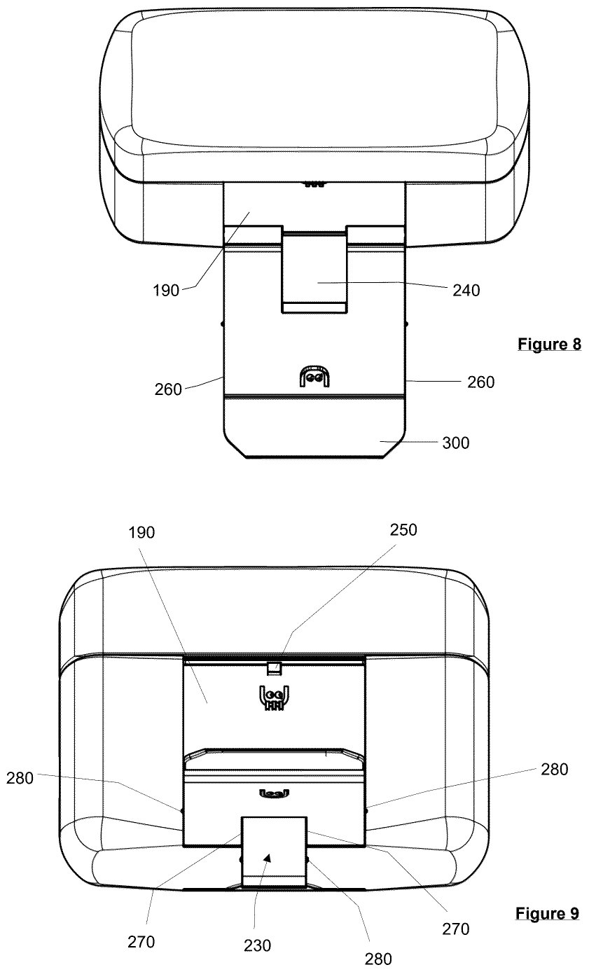

FIG. 8 shows a top perspective view of the embodiment of FIGS. 6 and 7;

FIG. 9 shows an underside perspective view of the embodiments of FIGS. 6 to 8;

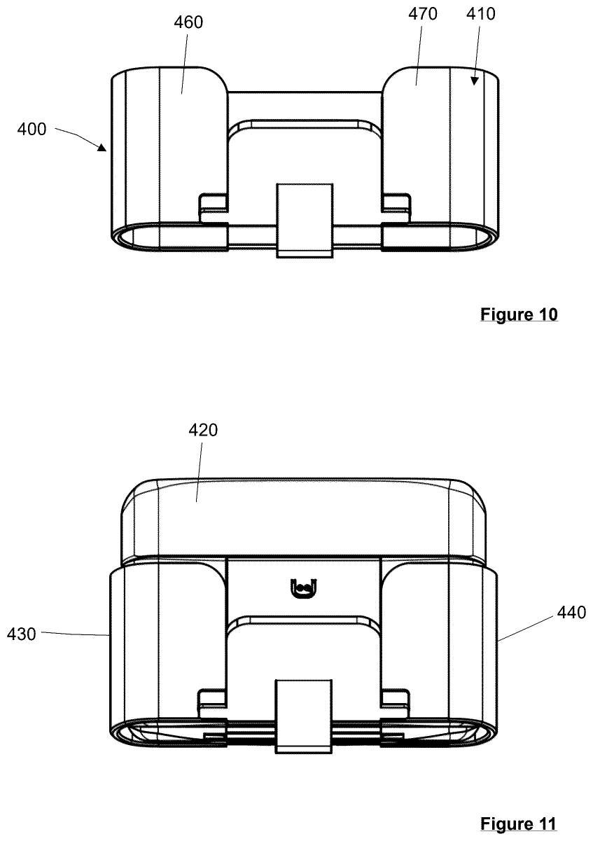

FIG. 10 shows a perspective view of a second embodiment of display apparatus;

FIG. 11 shows the display apparatus of FIG. 10 including an object;

FIG. 12 shows a side view of the embodiment of FIG. 10;

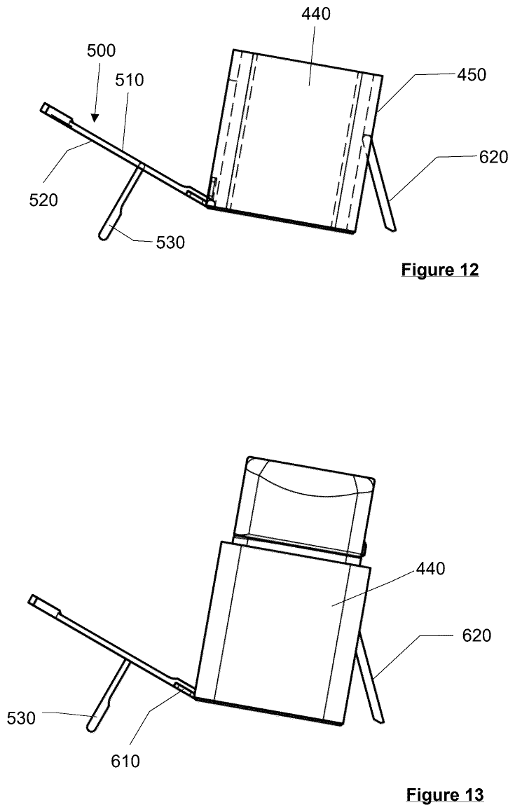

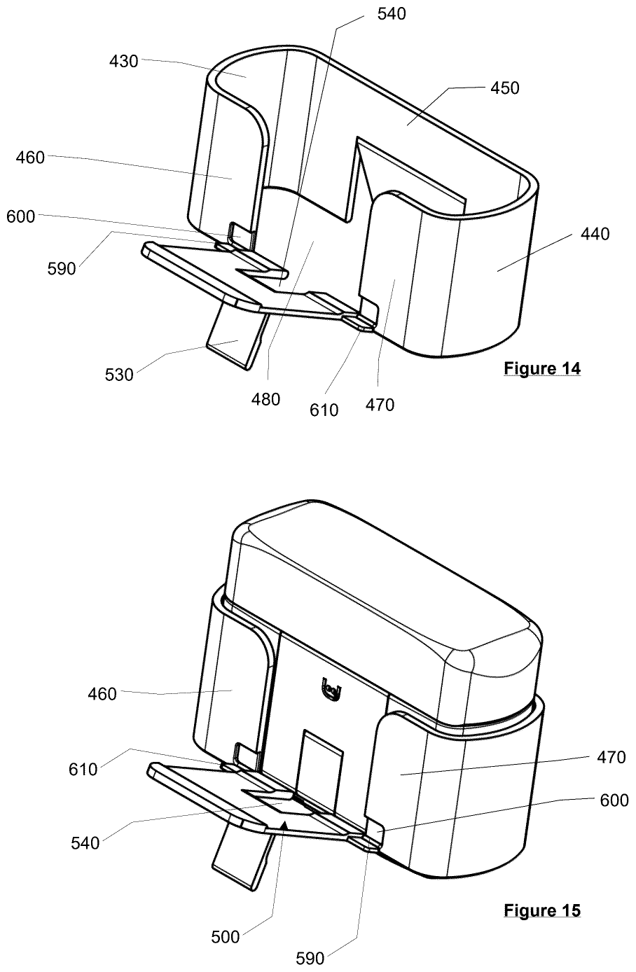

FIG. 13 shows a side view of the embodiment of FIG. 11;

FIG. 14 shows a perspective view of the embodiment of FIGS. 10 and 12; and

FIG. 15 shows an alternative perspective view of the embodiment of FIGS. 11 and 13.

Turning first to FIGS. 1 to 9, there is shown a first embodiment of display apparatus according to the present invention, generally indicated 100. The display apparatus in this example comprises a case for containing earbuds, though could conceivably be for storage of other items, comprise a power pack, or simply comprise a display stand. The display apparatus 100 comprises body section comprising a base 110 surrounded by an upstanding wall generally indicated 120. In particular, the wall 120 comprises front wall 130, rear wall 140 and side walls 150 and 160. The display apparatus 100 further comprises a lid 170 which is connected to the rear wall 140 via a hinge 180. Whilst not shown here, the interior of the display apparatus 100 comprises a recess or formations for retaining earbuds, though of course alternative formations could be provided for storage of other objects.

A shelf, generally indicated 200, is hingedly mounted adjacent to the front wall 130 and the base 110 of the display apparatus 100. Shelf 200 is substantially planar and comprises an upper surface 210 and a lower surface 220. The front wall 130 comprises a recess 190 which is shaped to receive the shelf 200. The shelf 200 is moveable between a stowed position, as best shown in FIG. 1, and a deployed position as best shown in FIG. 7. When in the stowed position, the shelf 200 is contained within the recess 190 and the lower surface 220 sits flush with the front wall 130. When in the deployed position, the shelf 200 extends away from the display apparatus 100 and the upper surface 210 of the shelf 200 provides a surface on which a device, such as a so-called “smart” or cellular phone, tablet, E-reader or the like can be displayed. The shelf can be deployed so that upstanding wall 120 of the body section is disposed in a position where it is tilted from the vertical by the shelf 200. The base 110 further comprises a USB charging port 340.

Shelf 200 further comprises foot generally indicated 230 which is pivotally mounted between the upper and lower surfaces 210,220 of the shelf 200. Foot 230 sits within a slot 240 in the shelf 200 when in a stowed position, and is pivotable to a deployed position, as shown for example in FIGS. 6 and 7, where it extends away from the lower surface 220 of the shelf 200. When deployed, the foot 230 can contact a surface and also cause the upstanding wall 120 of the body section of the display apparatus 100 to tilt from the vertical. When tilted in such a way, both the upper surface 210 of the shelf 200 and the front wall 130 provide a stable resting surface for an object such as a cellular telephone.

Recess 190 further comprises an abutment 250 so ensure that when the shelf is in the stowed position, the abutment retains the shelf 200 in the correct position.

Side edges 260,270 of both the shelf 200 and foot 230 comprise dimples 280 which locate into indentations 290 in the side edges of the slot 240 of the shelf 200 and a side wall of the recess 190 in order to clip the foot 230 and shelf 200 into respective stowed positions.

An upper edge of the shelf 200 further comprises a lip 300 which extends beyond the upper edge of the upstanding walls 120. Although not shown here, lid 170 comprises a slot to receive the lip 300, so that when the shelf 200 is in the stowed position and the lid 170 is closed, the shelf 200 is retained in the stowed position by the lip 300 being inserted into the lid 170. In order to deploy the shelf 200, the lid 170 will first need to be opened to release the lip 300 from the slot.

A best shown in FIGS. 2 and 6, a stand generally indicated 310 is pivotally mounted in the rear wall 140 of the display apparatus, said stand 310 being deployable between a stowed position and a deployed position. Rear wall 140 comprises a recess (not shown) in which the stand 310 is retained when in the stowed position. One or both side edges 320 of the stand 310 comprise a dimple 330 which is locatable into an indentation located on a side wall of the recess in the rear wall 140. The upstanding wall of the display apparatus can be tilted back onto the stand 310.

In certain embodiments the display apparatus may be provided with a stand 310 and shelf 200, or a shelf 200 comprising a foot 230, or a display apparatus comprising both a shelf 200 comprising a foot 230 and a stand 310, which will provide the most stability. Where a stand 310 and shelf 200 comprising a foot 230 are both provided, the foot 230 and stand 310 can be sized so that only the stand 310 and foot 230 contact a surface, or could be sized so that the foot 230, stand 310 and a side edge of the upstanding wall adjacent the rear wall 140 and base 110 contact the surface.

In use, a user may first raise open the lid 170 to remove lip 300 from the recess in the lid 470, and then pivot the shelf 200 to the deployed position so that it is substantially perpendicular to the front wall 130, and then pivot the foot 230 to the deployed position. The user may then pivot the stand 310 to the deployed position, and then rest the display apparatus on a surface. An object such as a cellular telephone or tablet may then be rested on the shelf and against the front wall 130.

Turning now to FIGS. 10 to 15, there is shown a second embodiment of display apparatus, generally indicated 400. The display apparatus 400 in this embodiment comprises an open-ended sleeve, generally indicated 410 into which an object such as a case for containing earbuds 420 (though could conceivably be for storage of other items) can be placed. The sleeve 410 comprises a body section which defines an upstanding wall. The wall 420 comprises a single strip which has a substantially rectangular cross section and has been shaped to comprise two side walls 430,440, rear wall 450 and opposed first and second ends 460,470 at the front of the sleeve 410 with a gap 480 defined therebetween. In alternative embodiments, the body section may also comprise a base.

The display apparatus 400 further comprises a shelf, generally indicated 500, which is hingedly mounted to the first and second ends 460,470 and is disposed in the gap 480. Shelf 500 is substantially planar and comprises an upper surface 510 and a lower surface 520. The shelf 500 is moveable between a stowed position, and a deployed position as best shown in FIG. 10. When in the stowed position, the shelf 500 is disposed between the first and second ends 460,470 in the gap 480 and sits flush with the wall 420. When in the deployed position, the shelf 500 extends away from the sleeve 410 and the upper surface 510 of the shelf 500 provides a surface on which an object to be viewed, such as a so-called “smart” or cellular phone, tablet, E-reader or the like can be displayed. The shelf can be deployed so that upstanding wall of the sleeve 410 is disposed in a position where it is tilted from the vertical by the shelf 500. When in the deployed position the sleeve 410 or the object contained therein acts as a backboard on which the object to be viewed can rest.

Shelf 500 further comprises a foot generally indicated 530 which is pivotally mounted between the upper and lower surfaces 510,520 of the shelf 200. Foot 530 sits within a slot 540 in the shelf 500 when in a stowed position, and is pivotable to a deployed position, as shown for example in FIGS. 10 and 12, where it extends away from the lower surface 520 of the shelf 500. When deployed, the foot 530 can contact a surface and also cause the sleeve 410 display apparatus 400 to tilt from the vertical.

The shelf 500 is connected at a lower edge to the first and second ends 460,470 of the sleeve 410 with hinges 590. The first and second ends 460,470 comprise recesses 600 above each hinge 590, and the shelf 500 comprises ears 610 positioned on side edges of the shelf 500 positioned across from the recesses 600. When in the stowed position, the ears 610 abut recesses 600 to prevent the shelf 500 from being pushed into the interior of the sleeve.

A best shown in FIGS. 12 and 13, a stand 620 is pivotally mounted in the rear wall 450 of the display apparatus, said stand 620 being deployable between a stowed position and a deployed position. Rear wall 450 comprises a recess (not shown) in which the stand 620 is retained when in the stowed position. One or both side edges of the stand may comprise a dimple which is locatable into an indentation located on a side wall of the recess in the rear wall 450. When the sleeve 410 is tilted back, the sleeve 410 rests on the stand 620.

In use, a user may insert an object such as an earbud case 420 inside the sleeve 410 and then pivot the shelf 500 to the deployed position so that it is substantially perpendicular to the first and second ends 460,470, and then pivot the foot 530 to the deployed position. The user may then pivot the stand 620 to the deployed position, and then rest the display apparatus 400 on a surface. An object such as a cellular telephone or tablet may then be rested on the shelf and against the first and second ends 460,470.

We claim:

1. Display apparatus comprising:
a body section, the body section comprising an upstanding wall; and
a shelf, the shelf being pivotally mounted to the body section, and moveable between a stowed position and a deployed position, wherein, when the shelf is in the deployed position, the shelf is pivoted away from the upstanding wall so as to provide a surface for retaining an object, and wherein the upstanding wall of the body section is disposed in a position where it is tilted from the vertical by the shelf.

2. Display apparatus as claimed in claim 1, wherein the shelf is pivotally mounted adjacent a lower edge of the upstanding wall.

3. Display apparatus as claimed in claim 1, wherein the shelf is substantially planar.

4. Display apparatus as claimed in claim 1, wherein the shelf further comprises a pivotally mounted foot, said foot being moveable between a stowed position adjacent the shelf, and a deployed position pivoted away from a lower surface of the shelf, the foot, when the foot and shelf are both in the deployed position, contacting a surface so as to tilt the upstanding wall away from the vertical.

5. Display apparatus as claimed in claim 1, wherein the body section further comprises a stand, the stand being pivotally mounted to the upstanding wall on an opposite side of the body section to the shelf, the stand moveable between a stowed position and a deployed position, wherein when the stand is in the deployed position, the stand contacts a surface so as to tilt the upstanding wall away from the vertical.

6. Display apparatus as claimed in claim 1, wherein the body section further comprises a base, and wherein the upstanding wall extends from a side edge of the base.

7. Display apparatus as claimed in claim 1, wherein the body section further comprises a lid.

8. Display apparatus as claimed in claim 7, wherein the lid is hingedly mounted to an upper edge of the upstanding wall of the body section.

9. Display apparatus as claimed in claim 8, wherein the hinge is disposed on an opposed side of the body section to the shelf.

10. Display apparatus as claimed in claim 7, wherein the shelf comprises a clasp for clasping the lid into a closed position.

11. Display apparatus as claimed in claim 7, wherein the shelf extends beyond upstanding wall, and wherein the lid comprises an aperture to retain the shelf and prevent its deployment when the lid is shut.

12. Display apparatus as claimed in claim 1, wherein the body section defines an enclosure for the storage of an object.
